(19) United States
(12) Patent Application Publication
(10) Pub. No.: US 2026/0036637 A1
(43) Pub. Date: Feb. 5, 2026

(54) BATTERY UNIT VOLTAGE DETECTION DEVICE

(71) Applicant: Prime Planet Energy & Solutions, Inc., Tokyo (JP)

(72) Inventor: Hideyuki SASAO, Ono-shi (JP)

(21) Appl. No.: 19/269,039

(22) Filed: Jul. 15, 2025

(30) Foreign Application Priority Data
Aug. 5, 2024 (JP) 2024-129089

(51) Int. Cl. G01R 31/3835; H01M 10/48

(52) U.S. Cl. CPC G01R 31/3835; H01M 10/482

(57) ABSTRACT

A battery unit voltage detection device includes: a battery unit including a plurality of battery cells; a voltage detection means being electrically connected to the battery unit and detecting a voltage value of the battery unit; a first capacitor being electrically connected to a positive electrode end of the battery unit and a negative electrode end of the battery unit; a second capacitor being electrically connected to the positive electrode end of the battery unit and the negative electrode end of the battery unit, and disposed closer to the voltage detection means than the first capacitor; a voltage divider resistor disposed between the battery unit and the first capacitor, and dividing a voltage of the battery unit; a battery side switch disposed between the battery unit and the first capacitor; and a detection side switch disposed between the first capacitor and the second capacitor.

### CROSS REFERENCE TO RELATED APPLICATIONS

The present application claims priority from Japanese Patent Application No. 2024-129089 filed on Aug. 5, 2024, which is incorporated by reference herein in its entirety.

### BACKGROUND

The present invention relates to battery unit voltage detection devices.

JP 2002-291167 A, for example, discloses a flying capacitor-type battery voltage detection device. The battery voltage detection device is equipped with a battery unit including a plurality of battery cells, and a differential voltage detection circuit connected to the battery unit. A flying capacitor and an output-side sampling switch are provided between the battery unit and the differential voltage detection circuit.

In the battery voltage detection device, the voltage of the battery unit is read into the flying capacitor and is output to the differential voltage detection circuit through the output-side sampling switch.

### SUMMARY

The flying capacitor-type battery voltage detection device as disclosed in JP 2002-291167 A may require higher withstanding voltage components for the components such as the flying capacitor according to the increase in the voltage value of the battery unit. Using higher withstanding voltage components may increase the sizes of components or the number of components.

According to the present disclosure, a battery unit voltage detection device includes a battery unit including a plurality of battery cells, a voltage detection means, a first capacitor, a second capacitor, a voltage divider resistor, at least one battery side switch, and at least one detection side switch. The voltage detection means is electrically connected to the battery unit and detects a voltage value of the battery unit. The first capacitor is electrically connected to a positive electrode end of the battery unit and a negative electrode end of the battery unit. The second capacitor is electrically connected to the positive electrode end of the battery unit and the negative electrode end of the battery unit, and is disposed closer to the voltage detection means than the first capacitor. The voltage divider resistor is disposed between the battery unit and the first capacitor, and divides a voltage of the battery unit. The battery side switch is disposed between the battery unit and the first capacitor. The detection side switch is disposed between the first capacitor and the second capacitor.

With the battery unit voltage detection device as disclosed herein, the voltage of the battery unit is divided by the voltage divider resistor and is thereafter stored in the first capacitor or the second capacitor. As a result, it is unnecessary to use high-withstanding voltage capacitors for the first capacitor and the second capacitor. Therefore, it is possible to prevent the increase in component size the increase in the number of components, which result from high withstanding voltage.

### BRIEF DESCRIPTION OF THE DRAWINGS

FIG. 1 is a schematic view illustrating a battery system according to a first embodiment.

FIG. 2 is a schematic view illustrating a voltage detection device according to the first embodiment.

FIG. 3 is a flowchart illustrating the procedure of detecting a voltage value of a battery unit in the voltage detection device according to the first embodiment.

FIG. 4 is a schematic view illustrating a voltage detection device according to a second embodiment.

FIG. 5 is a schematic view illustrating a voltage detection device according to a third embodiment.

FIG. 6 is a flowchart illustrating the procedure of detecting a voltage value of a battery unit in the voltage detection device according to the third embodiment.

FIG. 7 is a schematic view illustrating a voltage detection device according to a fourth embodiment.

### DETAILED DESCRIPTION

Hereinbelow, embodiments of the technology according to the present disclosure will be described with reference to the drawings. It should be noted, however, that the embodiments disclosed herein are, of course, not intended to limit the invention. The drawings are schematic illustrations, and do not necessarily reflect any actual product. The features and components that exhibit the same effects are designated by the same reference symbols as appropriate, and the description thereof will not be repeated as appropriate.

### First Embodiment

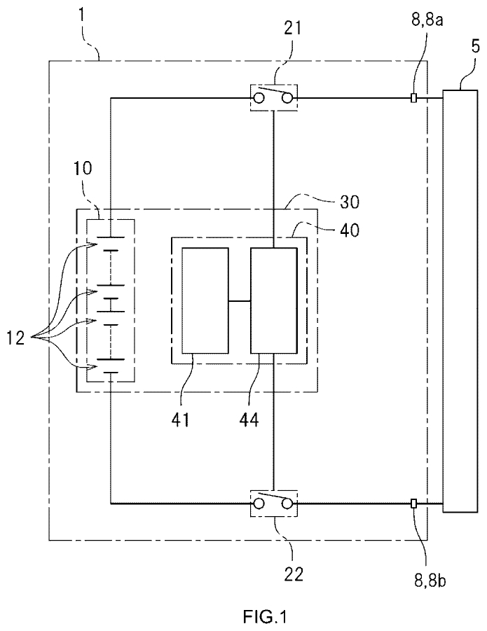

FIG. 1 is a schematic view illustrating a battery system 1 according to the present embodiment. As illustrated in FIG. 1, the battery system 1 is connected to a load 5. The battery system 1 is a system for supplying electric power to the load 5. The load 5 is not particularly limited to any type of load. The load 5 may be, for example, a drive device, such as an electric motor, or an inverter or the like, of a vehicle. The load 5 may be connected to a smoothing capacitor for reducing abrupt changes in electric current. Herein, the battery system 1 is incorporated in, for example, vehicles such as hybrid electric vehicles, plug-in hybrid electric vehicles, and battery electric vehicles. In this case, the battery system 1 is used as the power source to supply electric power to the electric motors for propelling the vehicles. The battery system 1 is, however, not limited to those for use in vehicles.

As illustrated in FIG. 1, the battery system 1 includes a pair of output terminals 8, a battery unit 10, a first contactor 21, a second contactor 22, and a voltage detection device 30 that detects the voltage of the battery unit 10 (hereinafter also referred to simply as a “voltage detection device 30”). The pair of output terminals 8 are connected to the load 5. The pair of output terminals 8 includes a positive electrode output terminal 8a and a negative electrode output terminal 8b.

The battery unit 10 is connected to the pair of output terminals 8 and is connected indirectly to the load 5 via the pair of output terminals 8. The battery unit 10 supplies electric power to the load 5. The load 5 may convert the electric power supplied from the battery unit 10 into motive power or supply regenerative power to the battery unit 10.

As illustrated in FIG. 1, the battery unit 10 includes a plurality of battery cells 12. The battery cells 12 are ones that are capable of being charged and discharged. For the battery cells 12, it may be possible to use secondary batteries, for example. Secondary batteries are batteries capable of repeated charging and discharging by the migration of charge carriers between a pair of electrodes (for example, positive electrode and negative electrode) through an electrolyte, for example. For the battery cells 12, it may be possible to use lithium-ion secondary batteries, nickel-metal hydride batteries, or the like, for example. In the present embodiment, the battery cells 12 are lithium-ion secondary batteries. The plurality of battery cells 12 are connected in series. Herein, the plurality of battery cells 12 are connected in series via a bus bar, not shown. However, it is also possible that the plurality of battery cells 12 may be connected in parallel. The number of battery cells 12 contained in the battery unit 10 is not limited to any particular number but may be a predetermined number. The number of battery cells 12 contained in the battery unit 10 may be determined as appropriate according to the magnitude of the electric power to be supplied to the load 5.

As illustrated in FIG. 1, the first contactor 21 is connected in series to the battery unit 10 (in other words, the plurality of battery cells 12 connected in series). Herein, the first contactor 21 is electrically connected to a positive electrode end of the battery unit 10. The first contactor 21 is disposed between the battery unit 10 and the positive electrode output terminal 8a. The first contactor 21 switches ON and OFF the electrical connection between the positive electrode end of the battery unit 10 and the load 5. Herein, contactors are, in other words, relays or switches.

As with the first contactor 21, the second contactor 22 is connected in series to the battery unit 10 (in other words, the plurality of battery cells 12 connected in series). Herein, the second contactor 22 is electrically connected to a negative electrode end of the battery unit 10. The second contactor 22 is disposed between the battery unit 10 and the negative electrode output terminal 8b. The second contactor 22 switches ON and OFF the electrical connection between the negative electrode end of the battery unit 10 and the load 5. In the present embodiment, the phrase “turning on a contactor” means that the contactor is in a connected state (i.e., in a closed state). The phrase “turning off a contactor” means that the contactor is in a disconnected state (i.e., in an open state). In the present embodiment, the first contactor 21 and the second contactor 22 are those that are capable of being switched ON and OFF electrically.

Next, the voltage detection device 30 according to the present embodiment will be described. The voltage detection device 30 is a device that detects a voltage value of the battery unit 10 (in other words, the plurality of battery cells 12 contained in the battery unit 10). In the present embodiment, it is possible that the battery unit 10 may be at a high voltage. For example, the battery unit 10 may result in a voltage value of about 650 V to about 700 V. For that reason, the voltage detection device 30 divides voltage when detecting the voltage value of the battery unit 10. The voltage detection device 30 is embodied by a so-called control circuit board.

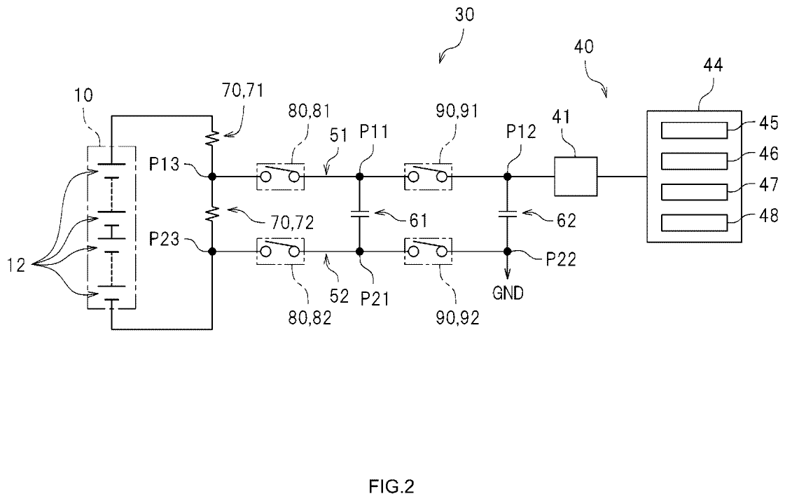

FIG. 2 is a schematic view illustrating the voltage detection device 30. As illustrated in FIG. 2, the voltage detection device 30 includes the previously-mentioned battery unit 10 and a voltage detection means 40. The voltage detection means 40 detects the voltage value of the battery unit 10. The configuration of the voltage detection means 40 is not limited to any particular configuration. Herein, the voltage detection means 40 includes an A/D converter 41 and a control device 44. The A/D converter 41 converts analog signals into digital signals. In the present embodiment, the A/D converter 41 acquires the voltage value of the battery unit 10 (more specifically, the voltage value after the voltage division) in an analog signal. Thereafter, the A/D converter 41 converts the analog signal into a digital signal and then outputs it to the control device 44.

The control device 44 controls charging and discharging of the battery unit 10. In addition, the control device 44 detects the voltage value of the battery unit 10. The configuration of the control device 44 is not limited to any particular configuration. The control device 44 may be, for example, a microcomputer. The control device 44 includes, for example, an I/F, a CPU, a ROM, and a RAM. The control device 44 may be composed of either a single computer or a plurality of computers.

In the present embodiment, as illustrated in FIGS. 1 and 2, the control device 44 is communicably connected to the first contactor 21, the second contactor 22 and the A/D converter 41. The control device 44 controls switching of the first contactor 21 and the second contactor 22 between ON and OFF. In addition, the control device 44 is able to detect the voltage value of the battery unit 10 by acquiring the voltage value as a digital signal from the A/D converter 41.

In the present embodiment, the voltage detection device 30 includes a positive electrode connecting wire 51 and a negative electrode connecting wire 52, as illustrated in FIG. 2. The positive electrode connecting wire 51 and the negative electrode connecting wire 52 are wires through which electric current flows. One end of the positive electrode connecting wire 51 is connected to the positive electrode end of the battery unit 10. The other end of the positive electrode connecting wire 51 is connected to the A/D converter 41 of the voltage detection means 40. One end of the negative electrode connecting wire 52 is connected to the negative electrode end of the battery unit 10. The other end of the negative electrode connecting wire 52 is grounded.

The voltage detection device 30 includes a first capacitor 61 and a second capacitor 62. The first capacitor 61 is electrically connected to the positive electrode end of the battery unit 10 and the negative electrode end of the battery unit 10. The first capacitor 61 is connected in parallel with the battery unit 10. In the present embodiment, the first capacitor 61 is connected to a positive electrode connecting point P11, which is at an intermediate portion of the positive electrode connecting wire 51, and to a negative electrode connecting point P21, which is at an intermediate portion of the negative electrode connecting wire 52. The second capacitor 62 is disposed closer to the voltage detection means 40 than the first capacitor 61. The second capacitor 62 is electrically connected to the positive electrode end of the battery unit 10 and the negative electrode end of the battery unit 10. The second capacitor 62 is connected in parallel with the battery unit 10 and the first capacitor 61. In the present embodiment, the second capacitor 62 is connected to a positive electrode connecting point P12 that is at an intermediate portion of the positive electrode connecting wire 51 and a negative electrode connecting point P22 that is at an intermediate portion of the negative electrode connecting wire 52. The positive electrode connecting point P12 is disposed closer to the voltage detection means 40 than the positive electrode connecting point P11, to which the first capacitor 61 is connected. The negative electrode connecting point P22 is disposed closer to the voltage detection means 40 than the negative electrode connecting point P21, to which the first capacitor 61 is connected. Note that the negative electrode connecting point P22 is connected to the ground.

As illustrated in FIG. 2, the voltage detection device 30 includes a voltage divider resistor 70. The voltage divider resistor 70 divides the voltage from the battery unit 10. The voltage divider resistor 70 is disposed between the battery unit 10 and the first capacitor 61. In the present embodiment, the voltage divider resistor 70 includes a first resistor 71 and a second resistor 72.

The first resistor 71 is electrically connected to the positive electrode end of the battery unit 10. The first resistor 71 is disposed closer to the battery unit 10 than the first capacitor 61. The first resistor 71 is connected in series to the positive electrode end of the battery unit 10. Herein, the first resistor 71 is disposed at an intermediate portion of the positive electrode connecting wire 51 that is closer to the battery unit 10 than the positive electrode connecting point P11. The second resistor 72 is electrically connected to the positive electrode end of the battery unit 10 and the negative electrode end of the battery unit 10. The second resistor 72 is connected in parallel with the battery unit 10. The second resistor 72 is disposed closer to the battery unit 10 than the first capacitor 61. Herein, the second resistor 72 is connected to a positive electrode connecting point P13, which is at an intermediate portion of the positive electrode connecting wire 51, and to a negative electrode connecting point P23, which is at an intermediate portion of the negative electrode connecting wire 52. The positive electrode connecting point P13 is disposed between the first resistor 71 and the positive electrode connecting point P11 to which the first capacitor 61 is connected. The negative electrode connecting point P23 is disposed closer to the battery unit 10 than the negative electrode connecting point P21, to which the first capacitor 61 is connected.

As illustrated in FIG. 2, the voltage detection device 30 includes a battery side switch 80 and a detection side switch 90. The battery side switch 80 is disposed between the battery unit 10 and the first capacitor 61. Herein, the battery side switch 80 is disposed between the voltage divider resistor 70 and the first capacitor 61. The battery side switch 80 is connected in series to the battery unit 10. In the present embodiment, the battery side switch 80 includes a first battery side switch 81 and a second battery side switch 82.

The first battery side switch 81 is electrically connected to the positive electrode end of the battery unit 10. The first battery side switch 81 is disposed closer to the battery unit 10 than the first capacitor 61 and also closer to the voltage detection means 40 than the first resistor 71. The first battery side switch 81 is connected in series to the positive electrode end of the battery unit 10. Herein, the first battery side switch 81 is disposed at an intermediate portion of the positive electrode connecting wire 51 that is closer to the battery unit 10 than the positive electrode connecting point P11. The first battery side switch 81 is disposed at an intermediate portion of the positive electrode connecting wire 51 that is closer to the voltage detection means 40 than the positive electrode connecting point P13. The second battery side switch 82 is electrically connected to the negative electrode end of the battery unit 10. The second battery side switch 82 is disposed closer to the battery unit 10 than the first capacitor 61. The second battery side switch 82 is connected in series to the negative electrode end of the battery unit 10. Herein, the second battery side switch 82 is disposed at an intermediate portion of the negative electrode connecting wire 52 that is closer to the battery unit 10 than the negative electrode connecting point P21. Also, the second battery side switch 82 is disposed at an intermediate portion of the negative electrode connecting wire 52 that is closer to the voltage detection means 40 than the negative electrode connecting point P23.

The detection side switch 90 is disposed between the first capacitor 62 and the second capacitor 62. The detection side switch 90 is connected in series to the battery unit 10. In the present embodiment, the detection side switch 90 includes a first detection side switch 91 and a second detection side switch 92.

The first detection side switch 91 is electrically connected to the positive electrode end of the battery unit 10. The first detection side switch 91 is disposed closer to the voltage detection means 40 than the first capacitor 61 and closer to the battery unit 10 than the second capacitor 62. The first detection side switch 91 is connected in series to the positive electrode end of the battery unit 10. Herein, the first detection side switch 91 is disposed at an intermediate portion of the positive electrode connecting wire 51 that is closer to the voltage detection means 40 than the positive electrode connecting point P11. The first detection side switch 91 is disposed at an intermediate portion of the positive electrode connecting wire 51 that is closer to the battery unit 10 than the positive electrode connecting point P12. The second detection side switch 92 is electrically connected to the negative electrode end of the battery unit 10. The second detection side switch 92 is disposed closer to the voltage detection means 40 than the first capacitor 61 and closer to the battery unit 10 than the second capacitor 62. The second detection side switch 92 is connected in series to the negative electrode end of the battery unit 10. Herein, the second detection side switch 92 is disposed at an intermediate portion of the negative electrode connecting wire 52 that is closer to the voltage detection means 40 than the negative electrode connecting point P21. Also, the second detection side switch 92 is disposed at an intermediate portion of the negative electrode connecting wire 52 that is closer to the battery unit 10 than the negative electrode connecting point P22.

In the present embodiment, the control device 44 of the voltage detection means 40 is communicably connected to the battery side switch 80 and the detection side switch 90. More specifically, the control device 44 is communicably connected to the first battery side switch 81, the second battery side switch 82, the first detection side switch 91, and the second detection side switch 92. The control device 44 controls switching of the first battery side switch 81, the second battery side switch 82, the first detection side switch 91, and the second detection side switch 92 between ON and OFF. In the present embodiment, the phrase “turning a switch ON” means that the switch is turned to an electrically connected state (i.e., in a closed state). The phrase “turning a switch OFF” means that the switch is turned to an electrically disconnected state (i.e., in an open state).

In the present embodiment, as illustrated in FIG. 2, the control device 44 includes a first controller 45, a second controller 46, a third controller 47, and a fourth controller 48. The first controller 45 to the fourth controller 48 may be implemented by a single processor or a plurality of processors, or may be implemented by circuitry.

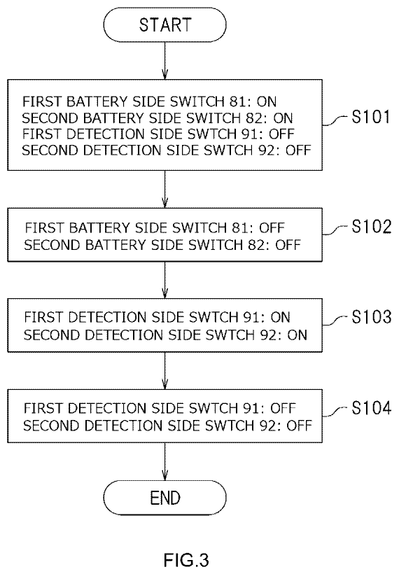

Next, the control procedure of the control device 44 of the voltage detection means 40 will be described with reference to the flowchart of FIG. 3. In the present embodiment, when detecting the voltage of the battery unit 10 with the voltage detection device 30, step S101 of FIG. 3 is performed first. At step S101, the first controller 45 shown in FIG. 2 turns the battery side switch 80 ON and turns the detection side switch 90 OFF. Specifically, the first controller 45 turns the first battery side switch 81 and the second battery side switch 82 ON, and turns the first detection side switch 91 and the second detection side switch 92 OFF. This brings the battery side switch 80 (the first battery side switch 81 and the second battery side switch 82 herein) to the closed state. Also, this brings the detection side switch 90 (the first detection side switch 91 and the second detection side switch 92 herein) to the open state.

When the control by the first controller 45 is performed, the voltage of the battery unit 10 is divided by the voltage divider resistor 70. This causes the divided voltage (for example, a predetermined amount of voltage) to be stored in the first capacitor 61. It should be noted that there is no particular limitation on the way in which the control device 44 determines whether or not voltage has been stored in the first capacitor 61. For example, it may be determined that voltage has been stored in the first capacitor 61 when a predetermined first elapsed time has passed after the control by the first controller 45 was performed. The first elapsed time is from 2 msec to 20 msec, and may be about 2 msec or about 20 msec, for example. The first elapsed time is, for example, 20 msec.

In the present embodiment, after voltage is stored in the first capacitor 61 subsequent to the control by the first controller 45, step S102 of FIG. 3 is performed. At step S102, the second controller 46 shown in FIG. 2 switches the first battery side switch 81 and the second battery side switch 82 from ON to OFF. Here, the first battery side switch 81 having been in the closed state is changed to the open state. Likewise, the second battery side switch 82 having been in the closed state is changed to the open state. Note that in step S102, the first detection side switch 91 and the second detection side switch 92 remain OFF (i.e., remain in the open state).

Next, at step S103 of FIG. 3, after the control by the second controller 46, the third controller 47 shown in FIG. 2 switches the first detection side switch 91 and the second detection side switch 92 from OFF to ON. Here, the first detection side switch 91 having been in the open state is changed to the closed state. Likewise, the second detection side switch 92 having been in the open state is changed to the closed state.

When the control by the third controller 47 is performed, the voltage stored in the first capacitor 61 (a predetermined amount of voltage, for example) is stored in the second capacitor 62. It should be noted that there is no particular limitation on the way in which the control device 44 determines whether or not voltage has been stored in the second capacitor 62. For example, as in the case with the first capacitor 61, it may be determined that voltage has been stored in the second capacitor 62 when a predetermined second elapsed time has elapsed after the control by the third controller 47 was performed. The second elapsed time is the same as the first elapsed time. However, the second elapsed time may be different from the first elapsed time. The second elapsed time is from 2 msec to 20 msec, and may be about 2 msec or about 20 msec, for example.

In the present embodiment, after voltage has been stored in the second capacitor 62, the A/D converter 41 acquires an analog signal based on the voltage stored in the second capacitor 62 and performs A/D conversion. The control device 44 receives a digital signal converted by the A/D converter 41, and based on the digital signal, it calculates a voltage value of the battery unit 10 that is a voltage value before the voltage division.

In the present embodiment, after voltage is stored in the second capacitor 62 subsequent to the control by the third controller 47, step S104 of FIG. 3 is performed. At step S104, the fourth controller 48 shown in FIG. 2 switches the first detection side switch 91 and the second detection side switch 92 from ON to OFF. Here, the first detection side switch 91 having been in the closed state is changed to the open state. Likewise, the second detection side switch 92 having been in the closed state is changed to the open state. Note that in step S104, the first battery side switch 81 and the second battery side switch 82 remain OFF (i.e., remain in the open state). In this way, the voltage detection device 30 is able to detect the voltage value of the battery unit 10.

As described above, in the present embodiment, the voltage detection device 30 of the battery unit 10 includes, as illustrated in FIG. 2, the battery unit 10 including the plurality of battery cells 12, the voltage detection means 40, the first capacitor 61, the second capacitor 62, the voltage divider resistor 70, the battery side switch 80, and the detection side switch 90. The voltage detection means 40 is electrically connected to the battery unit 10 to detect the voltage value of the battery unit 10. The first capacitor 61 is electrically connected to a positive electrode end of the battery unit 10 and a negative electrode end of the battery unit 10. The second capacitor 62 is electrically connected to the positive electrode end of the battery unit 10 and the negative electrode end of the battery unit 10, and is disposed closer to the voltage detection means 40 than the first capacitor 61. The voltage divider resistor 70 is disposed between the battery unit 10 and the first capacitor 61 to divide the voltage of the battery unit 10. The battery side switch 80 is disposed between the battery unit 10 and the first capacitor 61. The detection side switch 90 is disposed between the first capacitor 62 and the second capacitor 62. In the present embodiment, when detecting the voltage value of the battery unit 10, the voltage of the battery unit 10 is divided by the voltage divider resistor 70 and is thereafter stored in the first capacitor 61 or the second capacitor 62. As a result, it is unnecessary to use high-withstanding voltage capacitors for the first capacitor 61 and the second capacitor 62. Therefore, it is possible to prevent the increase in component size and the increase in the number of components, which result from high withstanding voltage.

In the present embodiment, as illustrated in FIG. 2, the battery side switch 80 is disposed between the voltage divider resistor 70 and the first capacitor 61. This enables switching the battery side switch 80 between ON and OFF to control whether or not the voltage divided by the voltage divider resistor 70 is to be applied to the first capacitor 61.

In the present embodiment, the voltage divider resistor 70 includes the first resistor 71, which is electrically connected to the positive electrode end of the battery unit 10, and the second resistor 72, which is electrically connected to the positive electrode end of the battery unit 10 and the negative electrode end of the battery unit 10. This allows the voltage applied from the battery unit 10 to be divided by the first resistor 71 and the second resistor 72.

In the present embodiment, as illustrated in FIG. 2, the battery side switch 80 includes the first battery side switch 81, which is electrically connected to the positive electrode end of the battery unit 10, and the second battery side switch 82, which is electrically connected the negative electrode end of the battery unit 10. The detection side switch 90 includes the first detection side switch 91, which is electrically connected to the positive electrode end of the battery unit 10, and the second detection side switch 92, which is electrically connected the negative electrode end of the battery unit 10. The voltage detection means 40 includes the A/D converter 41, which is electrically connected to the battery unit 10, and the control device 44, which is electrically connected to the A/D converter 41. The control device 44 includes the first controller 45, the second controller 46, the third controller 47, and the fourth controller 48. In step S101 of FIG. 3, the first controller 45 turns ON the first battery side switch 81 and the second battery side switch 82, and turns OFF the first detection side switch 91 and the second detection side switch 92. This prevents voltage from being applied to the second capacitor 62 when storing voltage in the first capacitor 61.

After voltage is stored in the first capacitor 61 subsequent to the control by the first controller 45, the second controller 46 switches OFF the first battery side switch 81 and the second battery side switch 82 in step S102 of FIG. 3. After the control by the second controller 46, the third controller 47 switches ON the first detection side switch 91 and the second detection side switch 92 in step S103 of FIG. 3. After voltage is stored in the second capacitor 62 subsequent to the control by the third controller 47, the fourth controller 48 switches OFF the first detection side switch 91 and the second detection side switch 92 in step S104 of FIG. 3. When the voltage stored in the first capacitor 61 is attempted to be stored in the second capacitor 62, current leakage to the battery unit 10 is made less likely to occur by turning ON the detection side switch 90 after turning OFF the battery side switch 80.

### Second Embodiment

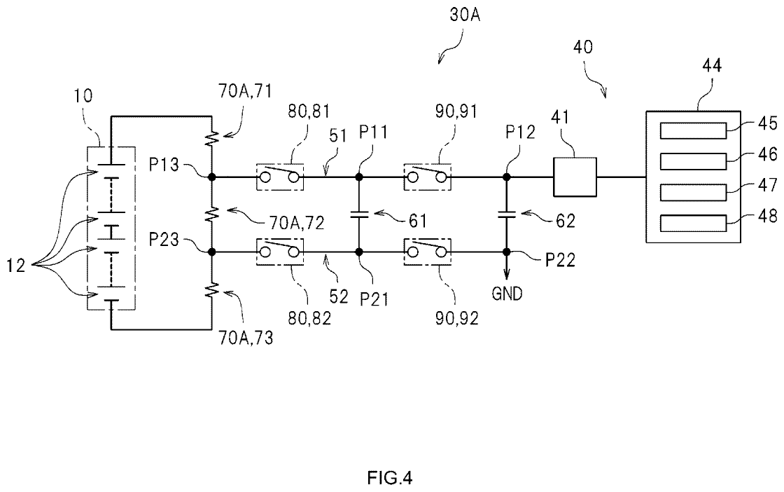

Next, a voltage detection device 30A according to a second embodiment will be described. FIG. 4 is a schematic view illustrating the voltage detection device 30A according to the second embodiment. The voltage detection device 30A (see FIG. 4) according to the second embodiment is different from the voltage detection device 30 (see FIG. 2) according to the first embodiment in the configuration of the voltage divider resistor 70.

In the present embodiment, as illustrated in FIG. 4, the voltage detection device 30A includes a voltage divider resistor 70A. The voltage divider resistor 70A includes a first resistor 71, a second resistor 72, and a third resistor 73. The first resistor 71 and the second resistor 72 here are respectively the same as the first resistor 71 and the second resistor 72 of the voltage detection device 30 according to the first embodiment, shown in FIG. 2. Adding the third resistor 73 to the voltage detection device 30 according to the first embodiment results in the voltage detection device 30A according to the second embodiment.

As illustrated in FIG. 4, the third resistor 73 is electrically connected to the negative electrode end of the battery unit 10. The third resistor 73 is disposed closer to the battery unit 10 than the first capacitor 61 and the second battery side switch 82. The third resistor 73 is connected in series to the negative electrode end of the battery unit 10. Herein, the third resistor 73 is disposed at an intermediate portion of the negative electrode connecting wire 52 that is closer to the battery unit 10 than the negative electrode connecting point P21, to which the first capacitor 61 is connected. Also, the third resistor 73 is disposed at an intermediate portion of the negative electrode connecting wire 52 that is closer to the battery unit 10 than the negative electrode connecting point P23, to which the second resistor 72 is connected.

In the present embodiment, the control procedure of the control device 44 of the voltage detection means 40 is the same as the control procedure in the first embodiment. That is, the present embodiment is allowed to detect the voltage value of the battery unit 10 by performing the control by the control device 44 according to the flowchart of FIG. 3.

The present embodiment is able to obtain the same advantageous effects as can be obtained by the first embodiment. Moreover, in the present embodiment, the voltage divider resistor 70 includes the third resistor 73 in addition to the first resistor 71 and a second resistor 72, as illustrated in FIG. 4. The third resistor 73 is electrically connected to the negative electrode end of the battery unit 10. This ensures a high resistance value by the voltage divider resistor 70A even if either one of the battery side switches 80 fails and remains to be in the closed state. As result, it is possible to prevent occurrence of high voltage current leakage to the battery unit 10.

### Third Embodiment

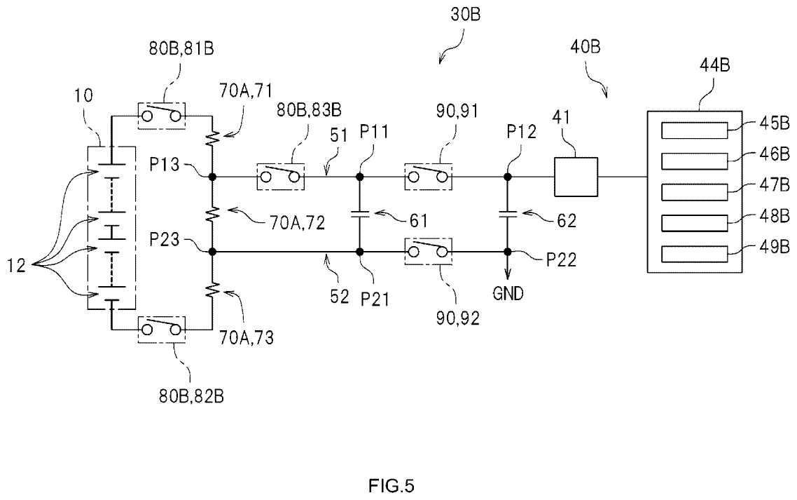

Next, a voltage detection device 30B according to a third embodiment will be described. FIG. 5 is a schematic view illustrating the voltage detection device 30B according to the third embodiment. The voltage detection device 30B (see FIG. 5) according to the third embodiment is different from the voltage detection device 30A (see FIG. 4) according to the second embodiment in the configuration and location of the battery side switch 80 and the configuration of the control device 44.

In the present embodiment, as illustrated in FIG. 5, the voltage detection device 30B includes the voltage divider resistor 70A, which is the same as that in the second embodiment, a battery side switch 80B, and a voltage detection means 40B. By replacing the battery side switch 80 with the battery side switch 80B and replacing the voltage detection means 40 with the voltage detection means 40B in the voltage detection device 30A (see FIG. 4) according to the second embodiment, the voltage detection device 30B according to the third embodiment is obtained.

In the present embodiment, as illustrated in FIG. 5, the battery side switch 80B includes a first battery side switch 81B, a second battery side switch 82B, and a third battery side switch 83B. The first battery side switch 81B is electrically connected to the positive electrode end of the battery unit 10. The first battery side switch 81B is disposed closer to the battery unit 10 than the first resistor 71 of the voltage divider resistor 70A.

Herein, the first battery side switch 81B is connected in series to the positive electrode end of the battery unit 10. The first battery side switch 81B is disposed at an intermediate portion of the positive electrode connecting wire 51 that is closer to the battery unit 10 than the first resistor 71.

The second battery side switch 82B is electrically connected to the negative electrode end of the battery unit 10. The second battery side switch 82B is disposed closer to the battery unit 10 than the third resistor 73 of the voltage divider resistor 70A. Herein, the second battery side switch 82B is connected in series to the negative electrode end of the battery unit 10. The second battery side switch 82B is disposed at an intermediate portion of the negative electrode connecting wire 52 that is closer to the battery unit 10 than the third resistor 73.

The third battery side switch 83B is electrically connected to the positive electrode end of the battery unit 10. The third battery side switch 83B is disposed closer to the battery unit 10 than the first capacitor 61 and also closer to the voltage detection means 40B than the first resistor 71 of the voltage divider resistor 70A. The third battery side switch 83B is connected in series to the positive electrode end of the battery unit 10. Herein, the third battery side switch 83B is disposed at an intermediate portion of the positive electrode connecting wire 51 that is closer to the battery unit 10 than the positive electrode connecting point P11, to which the first capacitor 61 is connected. The third battery side switch 83B is disposed at an intermediate portion of the positive electrode connecting wire 51 that is closer to the voltage detection means 40B than the positive electrode connecting point P13, to which the second resistor 72 of the voltage divider resistor 70A is connected.

Note that the third battery side switch 83B may be connected in series to the negative electrode end of the battery unit 10, not the positive electrode end of the battery unit 10. In this case, the third battery side switch 83B may be disposed at an intermediate portion of the negative electrode connecting wire 52 that is closer to the battery unit 10 than the negative electrode connecting point P21, to which the first capacitor 61 is connected, and is also closer to the voltage detection means 40B than the negative electrode connecting point P23, to which the second resistor 72 is connected.

In the present embodiment, as illustrated in FIG. 5, the voltage detection means 40B includes the A/D converter 41, which is the same as that in the first embodiment, and a control device 44B. Herein, the control device 44B includes a first controller 45B, a second controller 46B, a third controller 47B, a fourth controller 48B, and a fifth controller 49B. The first controller 45 to the fifth controller 49B may be implemented by a single processor or a plurality of processors, or may be implemented by circuitry.

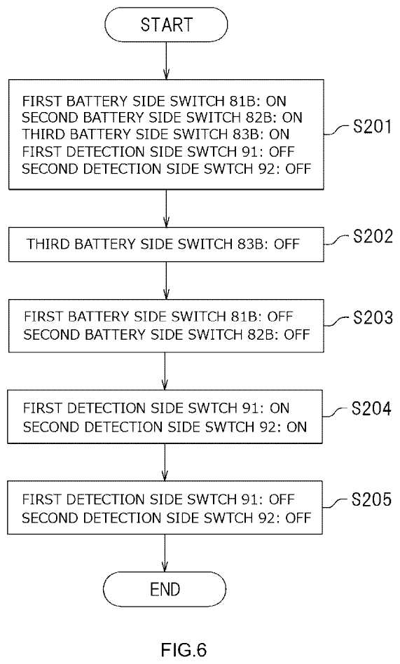

Next, the control procedure of the control device 44B of the voltage detection means 40B according to the present embodiment will be described with reference to the flowchart of FIG. 6. In the present embodiment, when detecting the voltage of the battery unit 10 with the voltage detection device 30B, step S201 of FIG. 6 is performed first. At step S201, the first controller 45B shown in FIG. 5 turns the battery side switch 80B ON and turns the detection side switch 90 OFF. The first controller 45B turns ON the first battery side switch 81B, the second battery side switch 82B, and the third battery side switch 83B, and turns OFF the first detection side switch 91 and the second detection side switch 92. This brings the battery side switch 80B (the first battery side switch 81B, the second battery side switch 82B, and the third battery side switch 83B herein) to the closed state. Also, this brings the detection side switch 90 (the first detection side switch 91 and the second detection side switch 92 herein) to the open state.

When the control by the first controller 45B is performed, the voltage of the battery unit 10 is divided by the voltage divider resistor 70A. This causes the divided voltage (for example, a predetermined amount of voltage) to be stored in the first capacitor 61. For example, the control device 44B determines that voltage is stored in the first capacitor 61 when a predetermined first elapsed time has passed after the control by the first controller 45B was performed.

In the present embodiment, after voltage is stored in the first capacitor 61 subsequent to the control by the first controller 45B, step S202 of FIG. 6 is performed. At step S202, the second controller 46B shown in FIG. 5 switches the third battery side switch 83B from ON to OFF. Here, the third battery side switch 83B having been in the closed state is changed to the open state. Next, at step S203 of FIG. 6, after the control by the second controller 46B, the third controller 47B shown in FIG. 5 switches the first battery side switch 81B and the second battery side switch 82B from ON to OFF. Herein, the first battery side switch 81B in the closed state is changed to the open state. Likewise, the second battery side switch 82 having been in the closed state is changed to the open state. In the present embodiment, when changing all the battery side switches 80B having been in the closed state to the open state, the third battery side switch 83B is first turned to the open state, and thereafter, the first battery side switch 81B and the second battery side switch 82B are turned to the open state. Note that in step S203, the first detection side switch 91 and the second detection side switch 92 remain OFF (i.e., remain in the open state).

Next, at step S204 of FIG. 6, after the control by the third controller 47B, the fourth controller 48B shown in FIG. 5 switches the first detection side switch 91 and the second detection side switch 92 from OFF to ON. Here, the first detection side switch 91 having been in the open state is changed to the closed state. Likewise, the second detection side switch 92 having been in the open state is changed to the closed state.

When the control by the fourth controller 48B is performed, the voltage stored in the first capacitor 61 (a predetermined amount of voltage, for example) is stored in the second capacitor 62. For example, the control device 44B determines that voltage is stored in the second capacitor 62 when a predetermined second elapsed time has passed after the control by the fourth controller 48B was performed. In the present embodiment, after voltage has been stored in the second capacitor 62, the A/D converter 41 acquires an analog signal based on the voltage stored in the second capacitor 62 and performs A/D conversion. The control device 44B receives a digital signal converted by the A/D converter 41, and based on the digital signal, it calculates a voltage value of the battery unit 10 that is a voltage value before the voltage division.

In the present embodiment, after voltage is stored in the second capacitor 62 subsequent to the control by the fourth controller 48B, step S205 of FIG. 6 is performed. At step S205, the fifth controller 49B shown in FIG. 5 switches the first detection side switch 91 and the second detection side switch 92 from ON to OFF. Here, the first detection side switch 91 having been in the closed state is changed to the open state. Likewise, the second detection side switch 92 having been in the closed state is changed to the open state. Note that in step S205, the first battery side switch 81B, the second battery side switch 82B, and the third battery side switch 83B remain OFF (i.e., remain in the open state). In this way, the voltage detection device 30B is able to detect the voltage value of the battery unit 10.

Thus, the present embodiment is able to obtain the same advantageous effects as can be obtained by the first embodiment and the second embodiment. Moreover, in the present embodiment, as illustrated in FIG. 5, the battery side switch 80B includes the first battery side switch 81B, the second battery side switch 82B, and the third battery side switch 83B. The first battery side switch 81B is disposed closer to the battery unit 10 than the voltage divider resistor 70A and is electrically connected to the positive electrode end of the battery unit 10. The second battery side switch 82B is disposed closer to the battery unit 10 than the voltage divider resistor 70A and is electrically connected to the negative electrode end of the battery unit 10. The third battery side switch 83B is disposed between the voltage divider resistor 70A and the first capacitor 61. Thus, the first battery side switch 81B and the second battery side switch 82B are disposed closer to the battery unit 10 than the voltage divider resistor 70A. The third battery side switch 83B is disposed closer to the voltage detection means 40B than the voltage divider resistor 70A. This reduces heat generation of the voltage divider resistor 70A evenly by turning ON the first battery side switch 81B and the second battery side switch 82B only at the time when storing voltage in the first capacitor 61. As a result, it is possible to prevent the temperature increase of the voltage detection device 30B.

In the present embodiment, after voltage is stored in the first capacitor 61 subsequent to the control by the first controller 45B, the second controller 46B of the control device 44B switches OFF the third battery side switch 83B in step S202 of FIG. 6. After the control by the second controller 46B, the third controller 47B of the control device 44B switches OFF the first battery side switch 81B and the second battery side switch 82B in step S203 of FIG. 6. Thus, current leakage to the battery unit 10 is made less likely to occur by turning OFF the first battery side switch 81B and the second battery side switch 82B after voltage is stored in the first capacitor 61 and the third battery side switch 83B is turned OFF.

### Fourth Embodiment

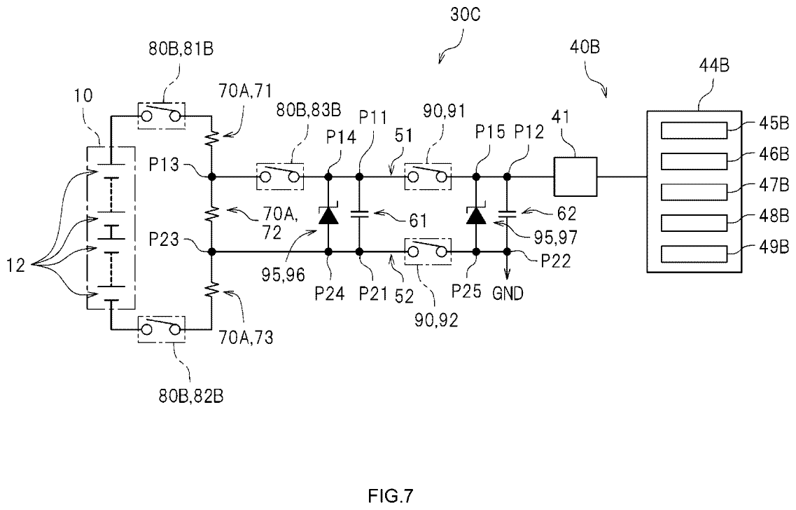

Next, a voltage detection device 30C according to a fourth embodiment will be described. FIG. 7 is a schematic view illustrating the voltage detection device 30C according to the fourth embodiment. The voltage detection device 30C (see FIG. 7) according to the fourth embodiment is that which a Zener diode 95 is added to the voltage detection device 30B (see FIG. 5) according to the third embodiment.

In the present embodiment, as illustrated in FIG. 7, the voltage detection device 30C further includes the Zener diode 95, compared to the voltage detection device 30B (see FIG. 5) according to the third embodiment. In other words, adding the Zener diode 95 to the voltage detection device 30B according to the third embodiment results in the voltage detection device 30C according to the fourth embodiment.

As illustrated in FIG. 7, the Zener diode 95 is electrically connected to the positive electrode end of the battery unit 10 and the negative electrode end of the battery unit 10. The Zener diode 95 is connected in parallel with the battery unit 10. The Zener diode 95 is disposed at least one of between the battery side switch 80B (specifically, the third battery side switch 83B) and the first capacitor 61 and between the detection side switch 90 and the second capacitor 62. In the present embodiment, the Zener diode 95 includes a first Zener diode 96 and a second Zener diode 97.

The first Zener diode 96 is electrically connected to the positive electrode end of the battery unit 10 and the negative electrode end of the battery unit 10. The first Zener diode 96 is connected in parallel with the battery unit 10. In the present embodiment, the first Zener diode 96 is disposed between the third battery side switch 83B of the battery side switch 80B and the first capacitor 61. The first Zener diode 96 is connected to a positive electrode connecting point P14, which is at an intermediate portion of the positive electrode connecting wire 51, and to a negative electrode connecting point P24, which is at an intermediate portion of the negative electrode connecting wire 52. The positive electrode connecting point P14 is disposed closer to the battery unit 10 than the positive electrode connecting point P11, to which the first capacitor 61 is connected. The positive electrode connecting point P14 is disposed closer to the voltage detection means 40B than the positive electrode connecting point P13, to which the second resistor 72 is connected, and the third battery side switch 83B. In addition, the negative electrode connecting point P24 is disposed closer to the battery unit 10 than the negative electrode connecting point P21, to which the first capacitor 61 is connected. The negative electrode connecting point P24 is disposed closer to the voltage detection means 40B than the negative electrode connecting point P23, to which the second resistor 72 is connected.

The second Zener diode 97 is electrically connected to the positive electrode end of the battery unit 10 and the negative electrode end of the battery unit 10. The second Zener diode 97 is connected in parallel with the battery unit 10. In the present embodiment, the second Zener diode 97 is disposed between the detection side switch 90 (specifically, the first detection side switch 91 and the second detection side switch 92) and the second capacitor 62. Herein, the second Zener diode 97 is connected to a positive electrode connecting point P15, which is at an intermediate portion of the positive electrode connecting wire 51, and to a negative electrode connecting point P25, which is at an intermediate portion of the negative electrode connecting wire 52. The positive electrode connecting point P15 is disposed closer to the voltage detection means 40B than the positive electrode connecting point P11 and the positive electrode connecting point P14.

The positive electrode connecting point P15 is disposed closer to the battery unit 10 than the positive electrode connecting point P12, to which the second capacitor 62 is connected. In addition, the negative electrode connecting point P25 is disposed closer to the voltage detection means 40B than the negative electrode connecting point P21 and the negative electrode connecting point P24. The negative electrode connecting point P25 is disposed closer to the battery unit 10 than the negative electrode connecting point P22, to which the second capacitor 62 is connected.

In the present embodiment, the control procedure of the control device 44B of the voltage detection means 40B is the same as the control procedure in the third embodiment.

That is, the present embodiment is allowed to detect the voltage value of the battery unit 10 by performing the control by the control device 44B according to the flowchart of FIG. 6.

The present embodiment is able to obtain the same advantageous effects as can be obtained by the first to third embodiments. Furthermore, in the present embodiment, the Zener diode 95 is disposed at least one of between the third battery side switch 83B and the first capacitor 61 and between the detection side switch 90 and the second capacitor 62, as illustrated in FIG. 7. Thereby, even if a failure occurs in the battery side switch 80B, the detection side switch 90, or the voltage divider resistor 70A or if the positive electrode and the negative electrode of the battery unit 10 are incorrectly connected inversely, the Zener diode 95 allows the components disposed closer to the voltage detection means 40B than the Zener diode 95 to be unlikely to fail.

As has been described above, the present description contains the disclosure as set forth in the following items.

### Item 1

A battery unit voltage detection device including:
a battery unit including a plurality of battery cells;
a voltage detection means being electrically connected to the battery unit and detecting a voltage value of the battery unit;
a first capacitor being electrically connected to a positive electrode end of the battery unit and a negative electrode end of the battery unit;
a second capacitor being electrically connected to the positive electrode end of the battery unit and the negative electrode end of the battery unit, and disposed closer to the voltage detection means than the first capacitor;
a voltage divider resistor disposed between the battery unit and the first capacitor, and dividing a voltage of the battery unit;
at least one battery side switch disposed between the battery unit and the first capacitor; and
at least one detection side switch disposed between the first capacitor and the second capacitor.

### Item 2

The battery unit voltage detection device according to item 1, wherein the at least one battery side switch is disposed between the voltage divider resistor and the first capacitor.

### Item 3

The battery unit voltage detection device according to item 2, wherein:
the at least one battery side switch includes:
   a first battery side switch electrically connected to the positive electrode end of the battery unit; and
   a second battery side switch electrically connected to the negative electrode end of the battery unit;
the at least one detection side switch includes:
   a first detection side switch electrically connected to the positive electrode end of the battery unit; and
   a second detection side switch electrically connected to the negative electrode end of the battery unit;
the voltage detection means includes:
   an A/D converter electrically connected to the battery unit; and
   a control device electrically connected to the A/D converter; and
the control device includes:
   a first controller turning the first battery side switch and the second battery side switch ON and turning the first detection side switch and the second detection side switch OFF;
   a second controller turning the first battery side switch and the second battery side switch OFF after voltage is stored in the first capacitor subsequent to a control by the first controller;
   a third controller turning the first battery side switch and the second battery side switch ON after a control by the second controller; and
   a fourth controller turning the first battery side switch and the second battery side switch OFF after voltage is stored in the second capacitor subsequent to a control by the third controller.

### Item 4

The battery unit voltage detection device according to item 1, wherein:
the voltage divider resistor includes:
   a first resistor electrically connected to the positive electrode end of the battery unit; and
   a second resistor electrically connected to the positive electrode end of the battery unit and the negative electrode end of the battery unit.

### Item 5

The battery unit voltage detection device according to item 4, wherein the voltage divider resistor includes a third resistor electrically connected to the negative electrode end of the battery unit.

### Item 6

The battery unit voltage detection device according to item 5, wherein:
the at least one battery side switch includes:
   a first battery side switch disposed closer to the battery unit than the voltage divider resistor and electrically connected to the positive electrode end of the battery unit;
   a second battery side switch disposed closer to the battery unit than the voltage divider resistor and electrically connected to the negative electrode end of the battery unit; and
   a third battery side switch disposed between the voltage divider resistor and the first capacitor.

### Item 7

The battery unit voltage detection device according to item 6, wherein:
the at least one detection side switch includes:
   a first detection side switch electrically connected to the positive electrode end of the battery unit; and
   a second detection side switch electrically connected to the negative electrode end of the battery unit;
the voltage detection means includes:
   an A/D converter electrically connected to the battery unit; and
   a control device electrically connected to the A/D converter; and
the control device includes:
   a first controller turning the first battery side switch, the second battery side switch, and the third battery side switch ON and turning the first detection side switch and the second detection side switch OFF;
   a second controller turning the third battery side switch OFF after voltage is stored in the first capacitor subsequent to a control by the first controller;
   a third controller turning the first battery side switch and the second battery side switch OFF after a control by the second controller; and
   a fourth controller turning the first detection side switch and the second detection side switch ON after a control by the third controller; and
   a fifth controller turning the first detection side switch and the second detection side switch OFF after voltage is stored in the second capacitor subsequent to a control by the fourth controller.

### Item 8

The battery unit voltage detection device according to item 6 or 7, further including a Zener diode disposed at least one of between the third battery side switch and the first capacitor and between the at least one detection side switch and the second capacitor, and electrically connected to the positive electrode end of the battery unit and the negative electrode end of the battery unit.

What is claimed is:

1. A battery unit voltage detection device comprising:
a battery unit including a plurality of battery cells;
a voltage detection means being electrically connected to the battery unit and detecting a voltage value of the battery unit;
a first capacitor being electrically connected to a positive electrode end of the battery unit and a negative electrode end of the battery unit;
a second capacitor being electrically connected to the positive electrode end of the battery unit and the negative electrode end of the battery unit, and disposed closer to the voltage detection means than the first capacitor;
a voltage divider resistor disposed between the battery unit and the first capacitor, and dividing a voltage of the battery unit;
at least one battery side switch disposed between the battery unit and the first capacitor; and
at least one detection side switch disposed between the first capacitor and the second capacitor.

2. The battery unit voltage detection device according to claim 1, wherein the at least one battery side switch is disposed between the voltage divider resistor and the first capacitor.

3. The battery unit voltage detection device according to claim 2, wherein:
the at least one battery side switch includes:
a first battery side switch electrically connected to the positive electrode end of the battery unit; and
a second battery side switch electrically connected to the negative electrode end of the battery unit;
the at least one detection side switch includes:
a first detection side switch electrically connected to the positive electrode end of the battery unit; and
a second detection side switch electrically connected to the negative electrode end of the battery unit;
the voltage detection means includes:
an A/D converter electrically connected to the battery unit; and
a control device electrically connected to the A/D converter; and
the control device includes:
a first controller turning the first battery side switch and the second battery side switch ON and turning the first detection side switch and the second detection side switch OFF;
a second controller turning the first battery side switch and the second battery side switch OFF after voltage is stored in the first capacitor subsequent to a control by the first controller;
a third controller turning the first detection side switch and the second detection side switch ON after a control by the second controller; and
a fourth controller turning the first detection side switch and the second detection side switch OFF after voltage is stored in the second capacitor subsequent to a control by the third controller.

4. The battery unit voltage detection device according to claim 1, wherein:
the voltage divider resistor includes:
a first resistor electrically connected to the positive electrode end of the battery unit; and
a second resistor electrically connected to the positive electrode end of the battery unit and the negative electrode end of the battery unit.

5. The battery unit voltage detection device according to claim 4, wherein the voltage divider resistor includes a third resistor electrically connected to the negative electrode end of the battery unit.

6. The battery unit voltage detection device according to claim 5, wherein:
the at least one battery side switch includes:
a first battery side switch disposed closer to the battery unit than the voltage divider resistor and electrically connected to the positive electrode end of the battery unit;
a second battery side switch disposed closer to the battery unit than the voltage divider resistor and electrically connected to the negative electrode end of the battery unit; and
a third battery side switch disposed between the voltage divider resistor and the first capacitor.

7. The battery unit voltage detection device according to claim 6, wherein:
the at least one detection side switch includes:
a first detection side switch electrically connected to the positive electrode end of the battery unit; and
a second detection side switch electrically connected to the negative electrode end of the battery unit;
the voltage detection means includes:
an A/D converter electrically connected to the battery unit; and
a control device electrically connected to the A/D converter; and
the control device includes:
a first controller turning the first battery side switch, the second battery side switch, and the third battery side switch ON and turning the first detection side switch and the second detection side switch OFF;
a second controller turning the third battery side switch OFF after voltage is stored in the first capacitor subsequent to a control by the first controller;
a third controller turning the first battery side switch and the second battery side switch OFF after a control by the second controller; and
a fourth controller turning the first detection side switch and the second detection side switch ON after a control by the third controller; and
a fifth controller turning the first detection side switch and the second detection side switch OFF after voltage is stored in the second capacitor subsequent to a control by the fourth controller.

8. The battery unit voltage detection device according to claim 6, further comprising a Zener diode disposed at least one of between the third battery side switch and the first capacitor and between the at least one detection side switch and the second capacitor, and electrically connected to the positive electrode end of the battery unit and the negative electrode end of the battery unit.
